(19) United States
(12) Patent Application Publication
(10) Pub. No.: US 2026/0159375 A1
(43) Pub. Date: Jun. 11, 2026

(54) SOUND CONVERSION DEVICE AND MICROPHONE

(71) Applicants: Yuki UCHIDA, Shiga (JP); Ayumu MURAKAMI, Shiga (JP)

(72) Inventors: Yuki UCHIDA, Shiga (JP); Ayumu MURAKAMI, Shiga (JP)

(73) Assignee: MMI SEMICONDUCTOR CO., LTD., Tokyo (JP)

(21) Appl. No.: 19/410,397

(22) Filed: Dec. 5, 2025

(30) Foreign Application Priority Data
Dec. 11, 2024 (JP) 2024-217024

(51) Int. Cl. B81B 3/00; H04R 1/08; H04R 19/04

(52) U.S. Cl. CPC B81B 3/0072; H04R 1/08; H04R 19/04; B81B 2201/0257; B81B 2203/0127; B81B 2203/0315; B81B 2203/0353; H04R 2201/003

(57) ABSTRACT

A sound conversion device includes a substrate having a cavity, a thin film disposed to cover the cavity, and a back plate facing the thin film in a thickness direction of the substrate, disposed on a side opposite to the substrate with respect to the thin film, and having a plurality of holes, wherein the plurality of holes include a first hole and a second hole aligned in a first direction, when viewed from the thickness direction of the substrate, the back plate includes a plate having the plurality of holes and facing the thin film, and a protrusion extending from the plate toward the thin film, and the protrusion is formed along at least a part of a periphery of the first hole between the first hole and the second hole.

The present application is based on and claims priority to Japanese patent application no. 2024-217024 filed on Dec. 11, 2024, with the Japan Patent Office, the entire contents of which are hereby incorporated by reference.

### BACKGROUND OF THE INVENTION

### 1. Field of the Invention

The disclosures herein relate to sound conversion devices and microphones.

### 2. Description of the Related Art

For example, an acoustic transducer including a substrate having a cavity, a vibrating electrode plate disposed above the substrate, and a fixed electrode plate facing the vibrating electrode plate above the substrate is known (see, e.g., Patent Literature (PTL) 1).

There is also known an acoustic transducer including a substrate having an opening, a back plate arranged so as to face the opening of the substrate, and a vibrating electrode film arranged to face the back plate with a gap provided between the vibrating electrode film and the back plate (see, e.g., PTL 2). The acoustic transducer converts displacement of the vibrating electrode film into a change in capacitance between the vibrating electrode film and the back plate. The back plate is provided with a projection extending toward the vibrating electrode film.

In a sound conversion device according to the related art, when a vibration of a thin film which is a vibrating electrode plate increases, there is a possibility that the thin film and the back plate may be damaged due to a collision between the thin film and the back plate.

The present disclosure aims to provide a sound conversion device capable of reducing stress concentration at the time of the collision between the thin film and the back plate and preventing damage to the thin film and the back plate.

### CITATION LIST

### Patent Literature

[PTL 1] Japanese Laid-Open Patent Publication no. 2015-56832

[PTL 2] International Publication no. 2016-143867

### SUMMARY OF THE INVENTION

A sound conversion device includes a substrate having a cavity, a thin film disposed to cover the cavity, and a back plate facing the thin film in a thickness direction of the substrate, disposed on a side opposite to the substrate with respect to the thin film, and having a plurality of holes formed in the back plate. The plurality of holes include a first hole and a second hole aligned in a first direction, when viewed from the thickness direction of the substrate. The back plate includes a plate having the plurality of holes and facing the thin film, and a protrusion extending from the plate toward the thin film, and the protrusion is formed along at least a part of a periphery of the first hole between the first hole and the second hole.

The present disclosure provides a sound conversion device capable of reducing stress concentration at the time of a collision between the thin film and the back plate and preventing damage to the thin film and the back plate.

### BRIEF DESCRIPTION OF THE DRAWINGS

FIG. 1 is an exploded perspective view illustrating a sound conversion device according to a first embodiment;

FIG. 2 is a plan view illustrating the sound conversion device according to the first embodiment;

FIG. 3 is a plan view illustrating a diaphragm;

FIG. 4 is a cross-sectional view illustrating a section taken along a line IV-IV in FIG. 2;

FIG. 5 is a partially enlarged plan view illustrating an enlarged portion of the back plate;

FIG. 6 is a cross-sectional view illustrating a section taken along a line VI-VI in FIG. 5;

FIG. 7A is a partially enlarged plan view illustrating an enlarged portion of a back plate according to a first modified example;

FIG. 7B is a partially enlarged plan view illustrating an enlarged portion of a back plate according to a second modified example;

FIG. 8 is a partially enlarged plan view illustrating an enlarged portion of a back plate according to a third modified example;

FIG. 9 is a cross-sectional view illustrating a MEMS microphone according to a second embodiment; and

FIG. 10 is a cross-sectional view illustrating a MEMS microphone according to a third embodiment.

### DESCRIPTION OF THE PREFERRED EMBODIMENTS

In the following, embodiments of the present invention will be described with reference to the accompanying drawings. In the present description and drawings, the same or corresponding constituent elements are denoted with the same reference numerals, and redundant description thereabout may be omitted.

### Sound Conversion Device 100 According to First Embodiment

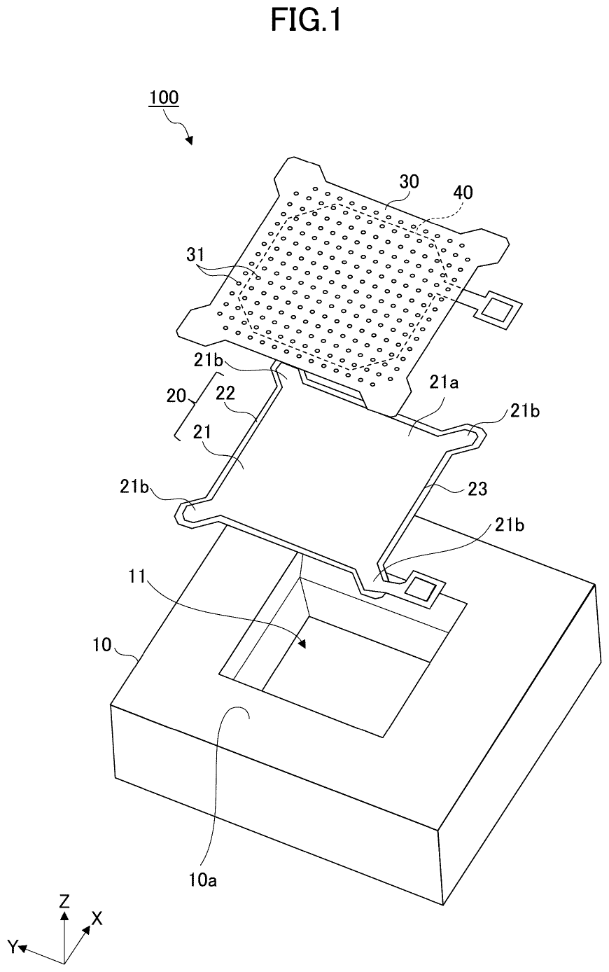

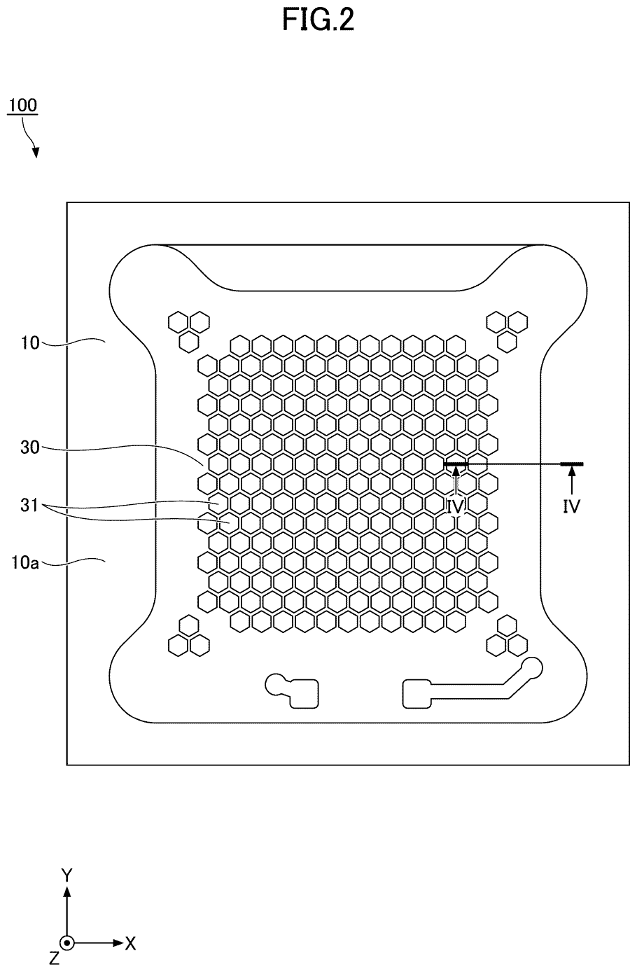

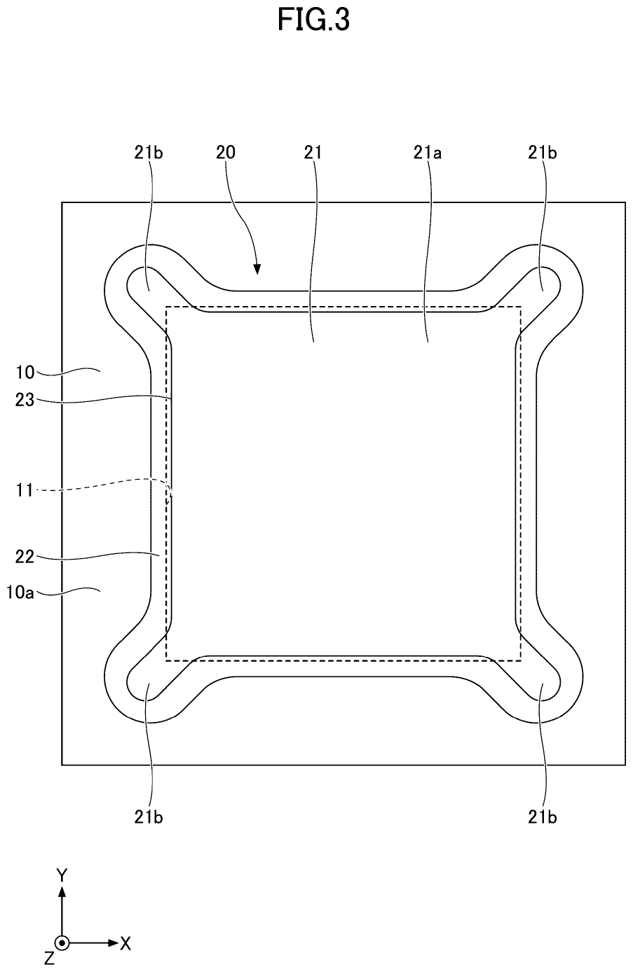

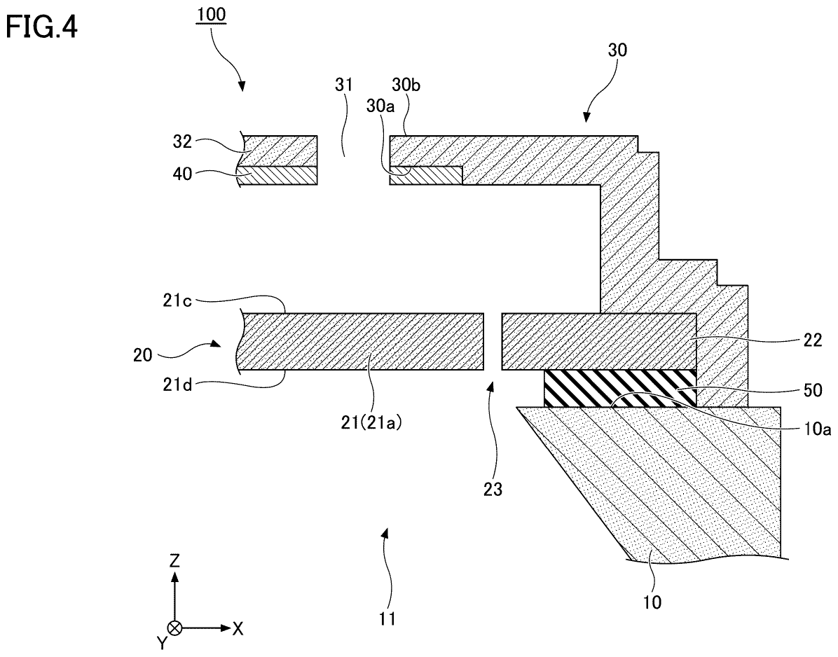

A sound conversion device 100 according to a first embodiment will be described with reference to FIGS. 1 to 6. FIG. 1 is an exploded perspective view illustrating the sound conversion device 100 according to the first embodiment. FIG. 2 is a plan view illustrating the sound conversion device 100 according to the first embodiment. FIG. 3 is a plan view illustrating a diaphragm 20. FIG. 4 is a cross-sectional view illustrating a section taken along the line IV-IV in FIG. 2. In each of the figures, an X-axis direction, a Y-axis direction, and a Z-axis direction, which are three orthogonal directions, are illustrated. The Z-axis direction is a thickness direction of a substrate 10. The Z-axis direction may be a top-bottom direction. In the following description, terms “top” and “bottom” may be used, but the sound conversion device 100 is not limited to such an orientation. For example, with the diaphragm 20 as a reference, a side where the back plate 30 is arranged may be referred to as “top” and a side where the substrate 10 is arranged may be referred to as “bottom”. The X-axis direction includes a direction indicated by an arrow and the opposite direction. Similarly, the Y-axis direction and the Z-axis direction include the direction indicated by the arrow and the opposite direction.

As shown in FIG. 1, the sound conversion device 100 includes a substrate 10, a diaphragm 20, and a back plate 30. As shown in FIG. 4, the sound conversion device 100 includes a fixed electrode 40 and a support member 50. The sound conversion device is also referred to as an acoustic transducer. The sound conversion device 100 can be used for MEMS microphones. The sound conversion device 100 is a capacitive element manufactured using MEMS technology. “MEMS” is an abbreviation for Micro Electro Mechanical System. The sound conversion device 100 can be used for other acoustic sensors, and can be used as a speaker.

### Substrate 10

The substrate 10 is formed of, for example, single crystal silicon. The substrate 10 may be formed into a cuboid shape, for example, by dicing. A cavity 11 penetrating in the Z-axis direction is formed in the substrate 10. The cavity 11 includes an opening. The cavity 11 has, for example, a rectangular shape when viewed from the Z-axis direction. The shape of the opening of the cavity 11 is not limited to a rectangular shape, but may have other shapes. The substrate 10 has a first surface 10a and a second surface facing each other in the Z-axis direction. The first surface 10a is a surface facing the diaphragm 20 in the Z-axis direction.

### Diaphragm 20

The diaphragm 20 has conductivity and is arranged so as to cover the cavity 11. The diaphragm 20 is a polysilicon thin film having conductivity. The diaphragm 20 is an example of a thin film. The diaphragm 20 is a vibrating electrode plate. The thickness direction of the diaphragm 20 is along the Z-axis direction. The diaphragm 20 has a movable film 21 and a fixed film 22. The movable film 21 is arranged so as to cover the cavity 11 in the Z-axis direction. As shown in FIG. 3, the movable film 21 includes a main body 21a having a substantially rectangular shape and a protrusion 21b extending outward from a corner of the main body 21a.

The main body 21a is arranged so as to overlap the cavity 11 when viewed from the Z-axis direction. The protrusion 21b is arranged so as to overlap the first surface 10a of the substrate 10 when viewed from the Z-axis direction. The protrusion 21b is fixed to the first surface 10a of the substrate 10. The protrusion 21b may be fixed to the substrate 10 via a support member 50 arranged between the protrusion 21b and the first surface 10a of the substrate 10 in the Z-axis direction. The main body 21a is a portion which can vibrate in the Z-axis direction. The main body 21a is an example of a deformable part of the thin film. The protrusion 21b is an example of a fixed part of the thin film.

The main body 21a of the movable film 21 has a first surface 21c and a second surface 21d opposite each other in the thickness direction (Z-axis direction) of the movable film 21. The first surface 21c is on a side facing the back plate 30, and the second surface 21d is on a side facing the cavity 11.

### Fixed Film 22

The fixed film 22 is disposed around the movable film 21 when viewed from the Z-axis direction. The fixed film 22 is formed so as to surround the movable film 21. The fixed film 22 is disposed so as to overlap the first surface 10a of the substrate 10 when viewed from the Z-axis direction. As shown in FIG. 4, the fixed film 22 is fixed to the first surface 10a of the substrate 10 via the support member 50.

### Slit 23

As shown in FIGS. 3 and 4, a slit 23 is formed between the movable film 21 and the fixed film 22 in the X-axis direction and the Y-axis direction. The slit 23 is a portion where the diaphragm 20 is not present. The slit 23 is formed so as to surround the movable film 21. The slit 23 has a predetermined width. The slit 23 is formed so as to penetrate the diaphragm 20 in the Z-axis direction. The slit 23 can be formed by etching a single polysilicon film. Thus, the movable film 21 and the fixed film 22 are divided.

### Back Plate 30

The back plate 30 is arranged on a side opposite to the substrate 10 with respect to the diaphragm 20 in the Z-axis direction. The back plate 30 may have a dome shape that expands toward the side opposite to the substrate 10.

The back plate 30 has a plate 32 facing the movable film 21 of the diaphragm 20 in the Z-axis direction. The thickness direction of the plate 32 is along the Z-axis direction. The plate 32 is arranged apart from the diaphragm 20 in the Z-axis direction. A predetermined space is formed between the diaphragm 20 and the plate 32. The plate 32 of the back plate 30 is arranged so as to cover the opening of the cavity 11 of the substrate 10 when viewed from the Z-axis direction.

A plurality of holes 31 penetrating in the Z-axis direction are formed in the plate 32 of the back plate 30. The plurality of holes 31 are arranged at predetermined intervals in the X-axis direction and the Y-axis direction. The plurality of holes 31 are acoustic holes (sound holes) for passing acoustic vibrations. The plate 32 of the back plate 30 has a first surface 30a and a second surface 30b opposite in the Z-axis direction. The first surface 30a is on the side of the diaphragm 20, and the second surface 30b is on the side opposite to the diaphragm 20.

The periphery of the back plate 30 is arranged at a position overlapping the first surface 10a of the substrate 10 when viewed from the Z-axis direction. The periphery of the back plate 30 is formed outside the plate 32. The periphery of the back plate 30 is disposed outside the diaphragm 20 in the X-axis direction and the Y-axis direction, and is fixed to the first surface 10a of the substrate 10.

### Fixed Electrode 40

The fixed electrode 40 is formed on the first surface 30a of the back plate 30. The fixed electrode 40 is arranged so as to face the main body 21a of the movable film 21 of the diaphragm 20 in the Z-axis direction. The fixed electrode 40 is arranged inward of the slit 23 in the X-axis direction and the Y-axis direction. The fixed electrode 40 is arranged at a position overlapping the cavity 11 of the substrate 10 when viewed from the Z-axis direction.

### Capacitance C

The diaphragm 20 and the fixed electrode 40 are arranged apart in the Z-axis direction and function as parallel plates. The main body 21a of the movable film 21 of the diaphragm 20 is a movable electrode and is displaced in the Z-axis direction by an action of sound pressure. As a result, capacitance C between the diaphragm 20 and the fixed electrode 40 changes. The sound conversion device 100 can sense sound by converting the change in the capacitance C into a voltage. The main body 21a of the movable film 21 is an example of a deformable part.

### Plurality of Holes 31

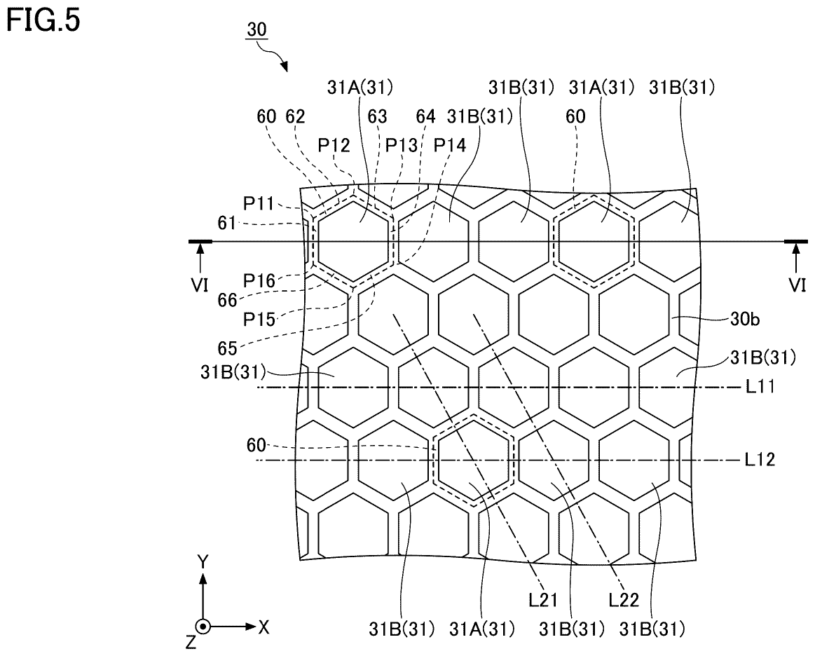

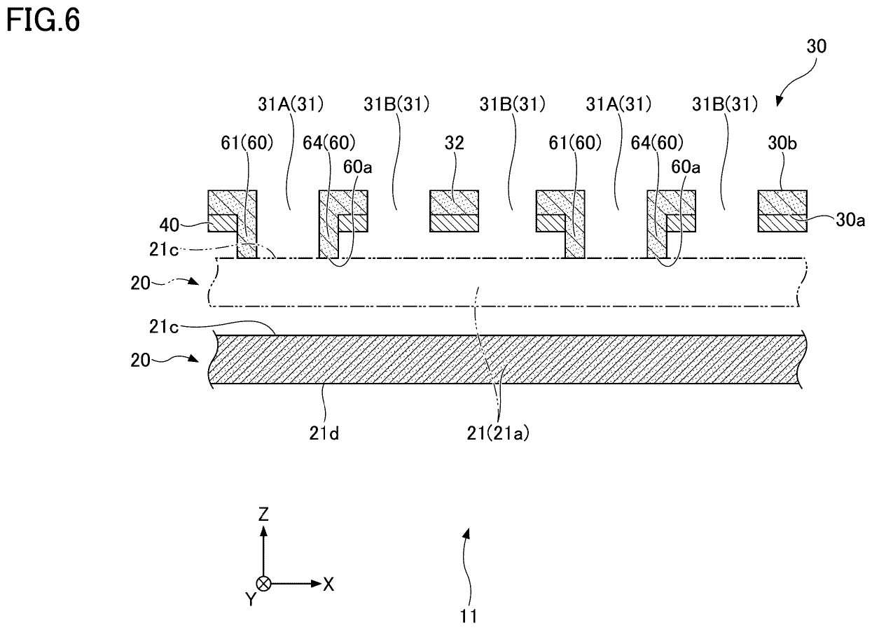

FIG. 5 is a partially enlarged plan view illustrating an enlarged portion of the back plate 30. FIG. 6 is a cross-sectional view illustrating a section taken along a line VI-VI in FIG. 5. As described above, a plurality of holes 31 are formed in the back plate 30. As shown in FIGS. 5 and 6, the plurality of holes 31 are arranged in the X-axis direction when viewed from the Z-axis direction. The “X-axis direction” is an example of the first direction. The plurality of holes 31 include a first hole 31A and a second hole 31B adjacent to each other in the X-axis direction.

A protrusion 60 described later is formed surrounding the first hole 31A. The first hole 31A and the second hole 31B may be arranged adjacent to each other in directions other than the X-axis direction. The plurality of first holes 31A are arranged apart in the X-axis direction, for example. The plurality of second holes 31B may be arranged between the plurality of first holes 31A in the X-axis direction. A part of the protrusion 60 is arranged around the second hole 31B.

The plurality of holes 31 may be formed to form a hexagon when viewed from the Z-axis direction. The plurality of holes 31 are arranged in a honeycomb pattern when viewed from the Z-axis direction.

The plurality of holes 31 may, for example, form a plurality of rows arranged along the lines L11 and L12. The lines L11 and L12 extend in the X-axis direction and are arranged apart in the Y-axis direction. The lines L11 and L12 are arranged in the Y-axis direction. The plurality of holes 31 are arranged in parallel.

The plurality of holes 31 may, for example, form a plurality of rows arranged along the lines L21 and L22. The lines L21 and L22 extend so as to be inclined at a predetermined angle (not including a right angle) with respect to the lines L11 and L12. The lines L21 and L22 are inclined with respect to the X-axis direction and the Y-axis direction. The plurality of holes 31 may be arranged in a staggered pattern.

A term “staggered” may refer to an arrangement in which, for example, the plurality of holes 31 arranged along a line L11 and the plurality of holes 31 arranged along a line L12 are offset from each other in the direction in which the lines L11 and L12 extend. The term “staggered” may also refer to an arrangement in which the lines L11 and L12 and the lines L21 and L22 do not intersect at right angles, and an arrangement in which the plurality of holes 31 are arranged along the lines L11, L12, L21, and L22.

### Protrusion 60

As shown in FIGS. 5 and 6, the back plate 30 has a protrusion 60 extending from the plate 32 toward the movable film 21. The protrusion 60 is formed to surround the first hole 31A.

The portion of the plate 32 around the first hole 31A may be referred to as a beam. A plurality of beams are arranged so as to form a hexagon along the outline of the first hole 31A forming a hexagon. As shown in FIG. 5, the plurality of beams are arranged so as to form a hexagon with points P11 to 16 as vertices. Along the respective sides of the hexagon, the protrusion 60 is arranged so as to form a hexagon. The protrusion 60 is arranged so as to connect the points P11 to P16. The width of the protrusion 60 may be approximately half the width of the beam.

As shown in FIG. 5, the protrusion 60 has a first side 61, a second side 62, a third side 63, a fourth side 64, a fifth side 65, and a sixth side 66. The first side 61 connects the points P16 and P11. The second side 62 connects the points P11 and P12. The third side 63 connects the points P12 and P13. The fourth side 64 connects the points P13 and P14. The fifth side 65 connects the points P14 and P15. The sixth side 66 connects the points P15 and P16.

The first side 61 and the fourth side 64 are arranged apart in the X-axis direction and extend in the Y-axis direction. The first side 61 and the fourth side 64 face each other across the first hole 31A. The second side 62 and the fifth side 65 face each other across the first hole 31A. The third side 63 and the sixth side 66 face each other across the first hole 31A.

### Contact Between Protrusion 60 and Movable Film 21

In FIG. 6, the movable film 21 that is not displaced is shown as a solid line, and the movable film 21 in contact with the protrusion 60 is shown as a chain double-dash line. For example, when the pressure in the cavity 11 rises, the movable film 21 moves in a direction approaching the back plate 30. When the pressure in the cavity 11 increases, the movable film 21 comes into contact with the protrusion 60. Specifically, the first surface 21c of the movable film 21 contacts the bottom surface 60a of the protrusion 60. Thus, the movable film 21 can be prevented from coming into close contact with the back plate 30.

### Effect of Sound Conversion Device 100 According to First Embodiment

The sound conversion device 100 according to the first embodiment includes a substrate 10 having a cavity 11, a diaphragm (thin film) 20 disposed to cover the cavity 11, and a back plate 30 facing the diaphragm 20 in the Z-axis direction (in the thickness direction of the substrate 10), disposed on a side opposite to the substrate 10 with respect to the diaphragm 20, and having a plurality of holes 31. The plurality of holes 31 includes a first hole 31A and a second hole 31B arranged in the X-axis direction (first direction) when viewed from the Z-axis direction. The back plate 30 includes a plate 32 having the plurality of holes 31 and facing the diaphragm 20, and a protrusion 60 extending from the plate 32 toward the diaphragm 20. The protrusion 60 is formed along a part of the periphery of the first hole 31A between the first hole 31A and the second hole 31B.

In such a sound conversion device 100, when pressure is applied to the inside of the cavity 11, the movable film 21 of the diaphragm 20 moves in a direction approaching the plate 32 of the back plate 30 according to the increase in pressure. When the pressure inside the cavity 11 increases, the movable film 21 contacts the protrusion 60. Therefore, contact between the movable film 21 and the plate 32 of the back plate 30 is prevented. In the related sound conversion device, a point-shaped stopper is formed so as to extend from the back plate 30 toward the diaphragm 20. The sound conversion device 100 according to the present embodiment has a protrusion 60 formed along a part of the periphery of the first hole 31A. Since the protrusion 60 has a predetermined length, a contact area with the movable film 21 can be increased as compared with the point-shaped stopper. In the sound conversion device 100, the stress concentration when the movable film 21 and the protrusion 60 come into contact with each other can be reduced. As a result, damage to the movable film 21 and the back plate 30 can be prevented.

In the sound conversion device 100, the protrusion 60 is formed so as to surround the first hole 31A when viewed from the Z-axis direction. The protrusion 60 may be formed around the entire periphery of the first hole 31A. In the sound conversion device 100 having this configuration, the contact area between the movable film 21 and the protrusion 60 can be increased by forming the protrusion 60 so as to continue around the entire periphery of the first hole 31A. Thus, the stress concentration when the movable film 21 and the protrusion 60 come into contact with each other can be reduced, and damage to the movable film 21 and the back plate 30 can be prevented.

In the sound conversion device 100, the plurality of holes 31 may be arranged in a honeycomb pattern when viewed from the Z-axis direction. In such a sound conversion device 100, the plurality of holes 31 can be efficiently arranged. An area of the plurality of holes 31 per unit area can be increased. Thus, the area where the movable film 21 and the back plate 30 overlap can be reduced when viewed from the Z-axis direction, and thermal noise generated at the overlapping part can be reduced. This results in controlling against generation of thermal noise and in reducing noise in the sound conversion device 100.

The sound conversion device 100 has a plurality of rows in which the plurality of holes 31 are arranged in the X-axis direction, and the plurality of rows are arrayed in the Y-axis direction (second direction) intersecting the X-axis direction. The plurality of holes 31 may be arranged in parallel. In such a sound conversion device 100, the plurality of holes 31 can be efficiently arranged. The area of the plurality of holes 31 per unit area can be increased.

In the sound conversion device 100, the plurality of holes 31 may be arranged in a staggered pattern. In such a sound conversion device 100, the plurality of holes 31 can be efficiently arranged. The area of the plurality of holes 31 per unit area can be increased.

In the sound conversion device 100, the plurality of holes 31 may be formed in a hexagonal (polygonal) shape when viewed from the Z-axis direction.

### Back Plate 30B According to First Modified Example

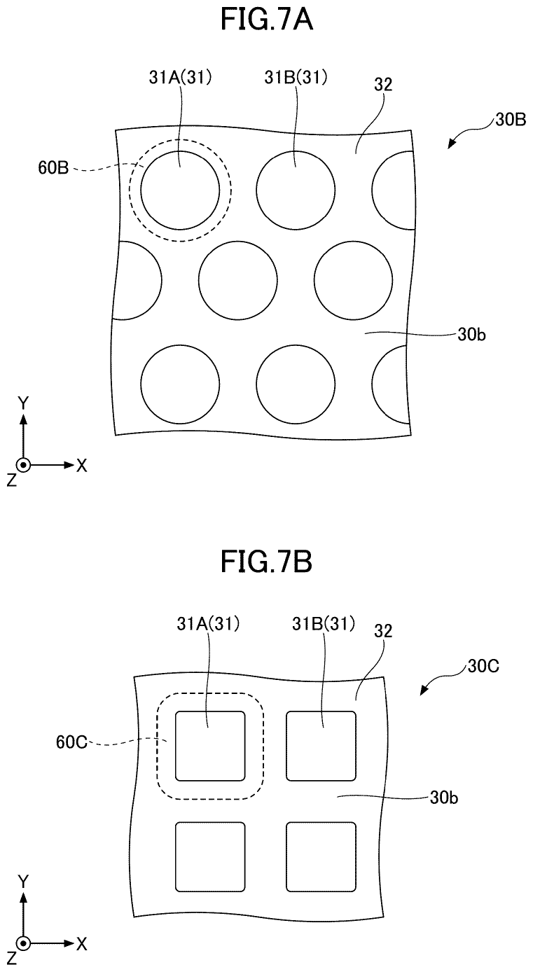

Next, a back plate 30B according to a first modified example will be described. FIG. 7A is a partially enlarged plan view illustrating an enlarged portion of the back plate 30B according to the first modified example. Instead of the back plate 30, the sound conversion device 100 may include a back plate 30B according to the first modified example.

A plurality of holes 31 may be circular when viewed from the Z-axis direction. The back plate 30B includes a circular protrusion 60B. The protrusion 60B is formed in a circular shape around the periphery of a first hole 31A.

The plurality of holes 31 may be arranged in a staggered pattern or in a grid pattern. The protrusion 60B is not required to be formed so as to continue around the entire periphery. An opening may be formed in the protrusion 60B.

Each of the plurality of holes 31 and protrusions 60B may be formed in an elliptical shape, a semicircular shape, or another shape.

### Back Plate 30C According to Second Modified Example

Next, a back plate 30C according to a second modified example will be described. FIG. 7B is a partially enlarged plan view illustrating an enlarged portion of the back plate 30C according to the second modified example. Instead of the back plate 30, the sound conversion device 100 may include the back plate 30C according to the second modified example.

Each of the plurality of holes 31 may be rectangular when viewed from the Z-axis direction. The back plate 30C includes a rectangular protrusion 60C. The protrusion 60C is formed in a rectangular shape around the periphery of the first hole 31A. The corners of the rectangular shape may be rounded.

Each of the plurality of holes 31 and the protrusion 60C may be formed in, for example, other polygonal shapes including a triangle, a diamond, a trapezoid, or another shape.

### Back Plate 30 According to Third Modified Example

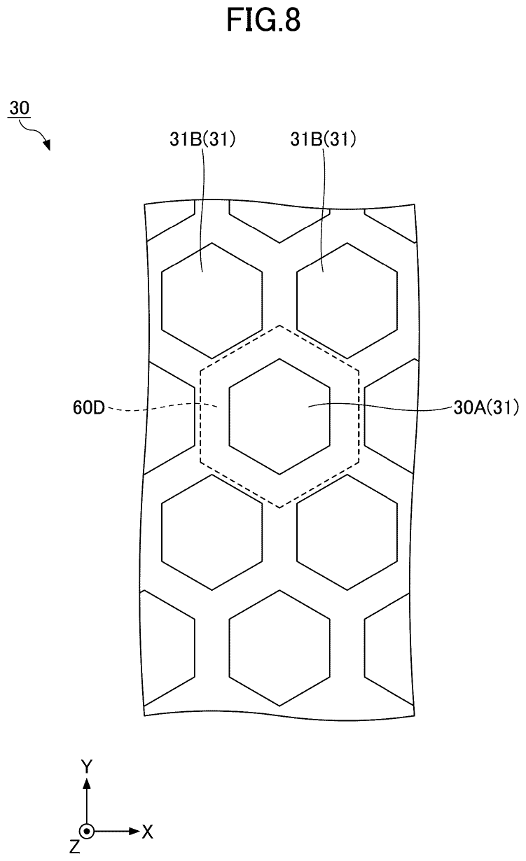

Next, a back plate 30 according to a third modified example will be described. FIG. 8 is a partially enlarged plan view illustrating an enlarged portion of the back plate 30 according to the third modified example. The back plate 30 according to the third modified example may have a protrusion 60D instead of the protrusion 60. The width of each side of the protrusion 60D is larger than the width of each side of the protrusion 60. The width of each side is the width in the direction intersecting the longitudinal direction of the side. The width of each side of the protrusion 60D may be about the same as the width of the beam around the first hole 31A. Thus, by making the width of each side of the protrusion 60D larger, the contact area between the movable film 21 and the protrusion 60D can be increased.

### Sound Conversion Device 100 According to Fourth Modified Example

Next, the sound conversion device 100 according to a fourth modified example will be described. In the sound conversion device 100 according to the fourth modified example, the diaphragm 20 is not required to have the fixed film 22 shown in FIG. 4. The movable film 21 may be formed to a position overlapping the first surface 10a of the substrate 10. The sound conversion device 100 according to the fourth modified example is not required to include a support member 50 for supporting the fixed film 22.

### MEMS Microphone 101 According to Second Embodiment

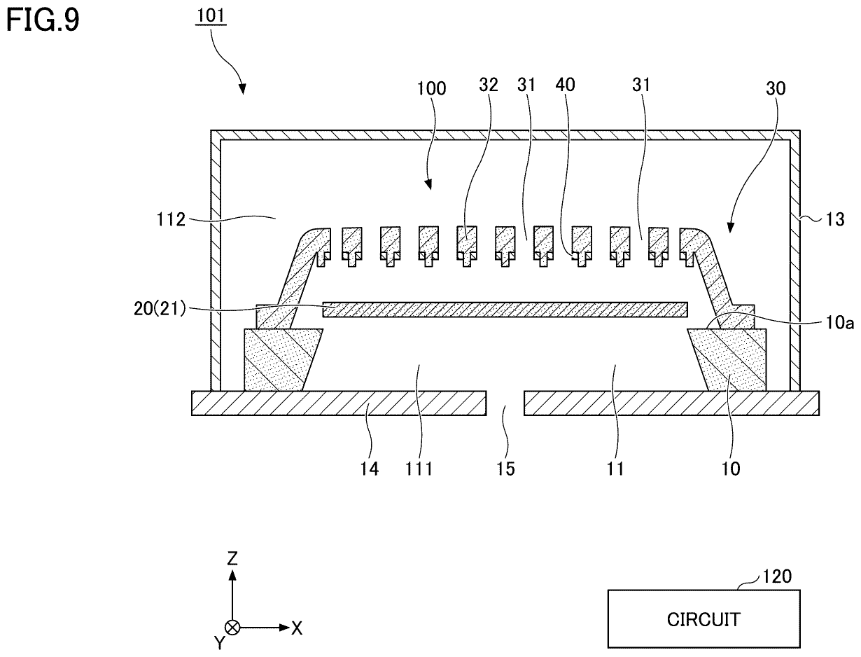

Next, a MEMS microphone 101 according to a second embodiment will be described. FIG. 9 is a cross-sectional view illustrating the MEMS microphone 101 according to the second embodiment. The MEMS microphone 101 includes the sound conversion device 100 according to the above-described embodiment. In the description of the MEMS microphone 101 according to the second embodiment, the same description as that of the sound conversion device 100 according to the above-described embodiment will be omitted.

The MEMS microphone 101 includes a sound conversion device 100, a housing 13, a bottom plate 14, and a circuit 120.

The circuit 120 is electrically connected to a diaphragm 20 which is a movable electrode and a fixed electrode 40. The circuit 120 converts the change of the capacitance C between the diaphragm 20 and the fixed electrode 40 into a voltage signal. The circuit 120 outputs the converted signal to the outside of the circuit 120.

The housing 13 has an opening and accommodates the sound conversion device 100. The housing 13 may be box-shaped. The housing 13 is arranged so as to cover the sound conversion device 100 from the back plate 30 side. The bottom plate 14 is disposed so as to close the opening of the housing 13. The sound conversion device 100 is arranged in a space surrounded by the housing 13 and the bottom plate 14. The thickness direction of the bottom plate 14 is along the Z-axis direction. The bottom plate 14 is arranged so as to close the bottom surface of the substrate 10. The bottom plate 14 is arranged on the opposite side of the substrate 10 from the diaphragm 20. A sound hole 15 which is a through-hole is formed in the bottom plate 14.

A first space 111 and a second space 112 are formed inside the housing 13. The first space 111 is a space between the diaphragm 20 and the bottom plate 14. The second space 112 is a space between the diaphragm 20 and the housing 13.

Thus, the sound conversion device 100 can be applied to the MEMS microphone 101.

### MEMS Microphone 101B According to Third Embodiment

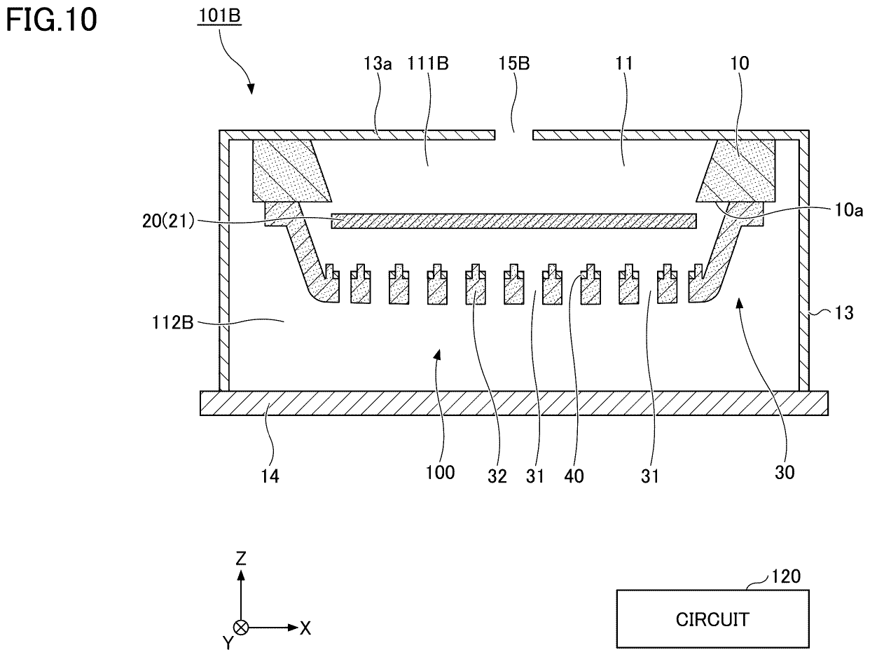

Next, the MEMS microphone 101B according to a third embodiment will be described. FIG. 10 is a cross-sectional view illustrating the MEMS microphone 101B according to the third embodiment. The MEMS microphone 101B according to the third embodiment differs from the MEMS microphone 101 according to the second embodiment in that the arrangement of the sound conversion device 100 and the sound hole 15B. In the description of the MEMS microphone 101B according to the third embodiment, the same description as that of the MEMS microphone 101B and the sound conversion device 100 according to the above-described embodiment will be omitted.

The MEMS microphone 101B includes a housing 13 and a bottom plate 14. A sound hole 15B is formed in the housing 13. The housing 13 has a top plate 13a facing the bottom plate 14 in the Z-axis direction. A sound hole 15B penetrating in the thickness direction is formed in the top plate 13a.

The substrate 10 of the sound conversion device 100 is attached to the top plate 13a of the housing 13. The sound hole 15B communicates with the cavity 11. The back plate 30 of the sound conversion device 100 is disposed opposite to the top plate 13a (closer to the bottom plate 14) with respect to the substrate 10.

A first space 111B and a second space 112B are formed inside the housing 13. The first space 111B is a space between the diaphragm 20 and the top plate 13a of the housing 13. The second space 112B is a space between the diaphragm 20 and the bottom plate 14.

Further, the present invention is not limited to these embodiments, and various variations and modifications may be made without departing from the scope of the present invention.

What is claimed is

1. A sound conversion device comprising:
a substrate having a cavity;
a thin film disposed to cover the cavity; and
a back plate facing the thin film in a thickness direction of the substrate, disposed on a side opposite to the substrate with respect to the thin film, and having a plurality of holes formed in the back plate, wherein:
the plurality of holes include a first hole and a second hole aligned in a first direction, when viewed from the thickness direction of the substrate;
the back plate includes:
a plate having the plurality of holes and facing the thin film; and
a protrusion extending from the plate toward the thin film; and
the protrusion is formed along at least a part of a periphery of the first hole between the first hole and the second hole.

2. The sound conversion device according to claim 1, wherein the protrusion is formed to surround the first hole when viewed from the thickness direction of the substrate.

3. The sound conversion device according to claim 1, wherein the plurality of holes are arranged in a honeycomb pattern when viewed from the thickness direction of the substrate.

4. The sound conversion device according to claim 1, further comprising a plurality of rows in which the plurality of holes are aligned in the first direction,
wherein the plurality of rows are arrayed in a second direction intersecting the first direction.

5. The sound conversion device according to claim 1, wherein the plurality of holes are arranged in a staggered pattern.

6. The sound conversion device according to claim 4, wherein each of the plurality of holes is formed in a circular shape when viewed from the thickness direction of the substrate.

7. The sound conversion device according to claim 4, wherein each of the plurality of holes is formed in a polygonal shape when viewed from the thickness direction of the substrate.

8. A microphone comprising:
the sound conversion device of claim 1; and
a circuit configured to output a signal output from the sound conversion device to an outside.

9. The microphone according to claim 8, further comprising:
a housing having an opening and configured to accommodate the sound conversion device; and
a bottom plate configured to close the opening of the housing, wherein:
a through-hole penetrating either the housing or the bottom plate in the thickness direction of the substrate and communicating with the cavity is formed; and
a first space defined between the thin film and the housing or the bottom plate in which the through-hole is formed; and
a second space defined between the thin film and the housing or the bottom plate in which the through-hole is not formed, both of the first space and the second space being formed within the housing.
